(19) United States
(12) Patent Application Publication
(10) Pub. No.: US 2024/0274514 A1
(43) Pub. Date: Aug. 15, 2024

(54) Electroless Die-Attach Process for Semiconductor Packaging

(71) Applicant: Wolfspeed, Inc., Durham, NC (US)

(72) Inventors: Afshin Dadvand, Durham, NC (US); Devarajan Balaraman, Apex, NC (US)

(21) Appl. No.: 18/169,492

(22) Filed: Feb. 15, 2023

(51) Int. Cl. H01L 23/495; H01L 21/48; H01L 23/00

(52) U.S. Cl. CPC H01L 23/49582; H01L 21/4821; H01L 23/49513; H01L 23/49562; H01L 24/29; H01L 24/32; H01L 24/48; H01L 24/73; H01L 2224/29624; H01L 2224/29644; H01L 2224/29655; H01L 2224/29664; H01L 2224/29666; H01L 2224/32245; H01L 2224/48245; H01L 2224/73265; H01L 2924/10272

(57) ABSTRACT

Semiconductor packages are provided. In one example, a semiconductor package may include a substrate comprising a through hole extending through the substrate. The semiconductor package may include a semiconductor die on the substrate. The semiconductor die may be overlapping the through hole. The through hole in the substrate may be at least partially filled with an electroless deposited portion.

### FIELD

The present disclosure relates generally to semiconductor device packaging.

### BACKGROUND

Semiconductor devices, including power semiconductor devices based on wide band gap materials, may be formed on a semiconductor wafer as part of a semiconductor fabrication process. The semiconductor wafer may be diced into many individual pieces, each containing one or more semiconductor devices. Each of these pieces may be a semiconductor die. The semiconductor die may need to be attached to other components as part of packaging of the semiconductor device. For instance, a semiconductor die, such as a wide band gap semiconductor die, may need to be attached to a conductive lead frame for use in a discrete power semiconductor package or a power module. Materials used to attach the semiconductor die to other components may need to provide a thermal, mechanical, and/or electrical connection of the semiconductor die to the other components.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor package. The semiconductor package may include a substrate comprising a through hole extending through the substrate. The semiconductor package may include a semiconductor die on the substrate. The semiconductor die may be overlapping the through hole. The through hole in the substrate may be at least partially filled with an electroless deposited portion.

Another example embodiment of the present disclosure is directed to a method. The method may include placing a semiconductor die on a substrate so that the semiconductor die overlaps a through hole extending through the substrate. The method may include performing an electroless deposition process to deposit an electroless deposited portion in the through hole such that the electroless deposited portion at least partially fills the through hole.

Another example embodiment of the present disclosure is directed to a power semiconductor device. The power semiconductor device may include a substrate. The power semiconductor device may include a power semiconductor die comprising a wide band gap semiconductor. The power semiconductor die may be coupled to the substrate with an electroless deposited portion.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of a semiconductor package according to example embodiments of the present disclosure;

FIG. 2 depicts a perspective top view of a semiconductor package according to example embodiments of the present disclosure;

FIG. 3 depicts a perspective bottom view of a semiconductor package according to example embodiments of the present disclosure;

FIG. 4 depicts an example semiconductor package for a power module according to example embodiments of the present disclosure;

FIG. 5 depicts a flow chart of an example method for performing an electroless die-attach process according to example embodiments of the present disclosure;

FIG. 6 depicts an example conductive adhesion layer and an example conductive catalytic layer on a semiconductor die according to example embodiments of the present disclosure;

FIG. 7 depicts an example electroless die-attach process according to example embodiments of the present disclosure;

FIG. 8 depicts an example electroless die-attach process according to example embodiments of the present disclosure;

FIG. 9 depicts an example electroless die-attach process according to example embodiments of the present disclosure;

FIG. 10 depicts a flow chart of an example method according to example embodiments of the present disclosure; and

FIG. 11 depicts a portion of an example electroless die-attach process according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to electroless die-attach processes for attaching a semiconductor die to a substrate in semiconductor applications and other electronics applications, such as wide band gap semiconductor device applications. In semiconductor packaging, thermal management is an important aspect of packaging design to address issues associated with degradation of a device at high temperatures. Thermal management is becoming increasingly more important with the continuous trends for high power packages as well as highly integrated systems with smaller features and higher currents.

Various technologies that are practiced in the semiconductor industry for die-attach present challenges and limitations, including challenges related to thermal loss. For example, semi-silver or full-silver sintering process techniques offer acceptable electrical, mechanical and thermal properties for die-attach applications. However, semi-silver or full-silver sintering process techniques may have a high cost and also may be at high risk of electromigration, high voiding/porosity, and high thermo-mechanical stresses. Eutectic Au80Sn20 techniques may also pose similar limitations. Semi-sintered or full-sintered copper is a lower cost option with lower performance due the high oxidation susceptibility of copper especially in small particle sizes. Semi-sintered or full-sintered copper may also pose challenges in requiring low temperature storage and a forming gas during a deposition process to reduce oxidation. Lead (Pb) based die-attach solutions are not optimal options for achieving low thermal resistance and efficient current or power density. In addition, lead (Pb) based die-attach materials do not meet certain lead-free certification standards.

Example aspects of the present disclosure are directed to an electroless die-attach process. The electroless die-attach process may attach a semiconductor die to a substrate, such as a conductive lead frame of a semiconductor package. The semiconductor die may be, for instance, a silicon carbide-based semiconductor die, a Group III nitride-based semiconductor die, a silicon-based semiconductor die, or other semiconductor die. In some examples, the substrate may have a through hole extending through the substrate. A semiconductor die may be placed on the substrate overlapping the through hole. The through hole may be at least partially filled with an electroless deposited portion to provide a thermal, electrical, and/or a mechanical connection of the semiconductor die to the substrate. As used herein, a first structure “overlaps” a second structure if an axis that is perpendicular to a major surface of the first structure passes through both the first structure and the second structure.

In some examples, a conductive adhesion layer may be deposited on a backside surface of the semiconductor die. The conductive adhesion layer may be, for instance, titanium. A thin conductive catalytic layer (e.g., about 25 nm to about 75 nm) of a conductive catalytic active metal material may be deposited on the conductive adhesion layer to provide a catalytic surface to initiate an electroless deposition process. In this way, the conductive adhesion layer may be between the semiconductor die and the conductive catalytic layer.

In some examples, the conductive adhesion layer may be titanium (Ti). In some examples, the conductive catalytic layer may be, for instance, gold (Au), palladium (Pd), nickel (Ni), or aluminum (Al) or may be an alloy containing gold (Au), palladium (Pd), nickel (Ni), or aluminum (Al) with other elements. Other metal layers may be deposited on the semiconductor die without deviating from the scope of the present disclosure.

A through hole that is smaller in area than an area of the semiconductor die may extend through the substrate. A die-attach material (e.g., die-attach film or die-attach paste) may be deposited around the through hole (e.g., surrounding the through hole) to hold the semiconductor die. The semiconductor die may be placed on the die-attach material overlapping the through hole. Other methods may be used to temporarily hold and/or bond the semiconductor die such that it is overlapping the through hole without deviating from the scope of the present disclosure, such as the use of metal and/or non-metal pastes.

In some examples, the structure of the through hole may include a recess and a stepped surface in the recess to accommodate the semiconductor die. The recess with stepped surface may hold the semiconductor die with or without a die-attach material. In some examples, a protective coating (e.g., photoresist or other protective coating) may be placed on the semiconductor die.

An electroless deposition process may be initiated from the backside of the die (e.g., with the conductive catalytic layer). For instance, the substrate with the semiconductor die may be placed in an electroless bath. An electroless deposited portion may grow in the through hole through the substrate and may become a part of the substrate. The backside of the substrate may not be electroless plated, for instance, if the substrate is copper because copper is not catalytically active for initiation of electroless process.

The electroless bath may include, for instance, a metal ion source, a reducing agent, and/or a complexing agent (e.g., chelating agent). The electroless bath may include additives such as a stabilizer to tune the properties of the electroless deposited portion.

Aspects of the present disclosure provide a number of technical effects and benefits. For instance, connection of the semiconductor die to a substrate through an electroless deposited portion may provide increased thermal performance relative to connection through a die-attach material. The interdiffusion of the metal atoms during and/or after the electroless process may provide a low-cost and direct die-attachment for the semiconductor die that may avoid issues relating to, for instance, electromigration, high voiding/porosity, and high thermo-mechanical stresses that may be exhibited by certain die-attach materials.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

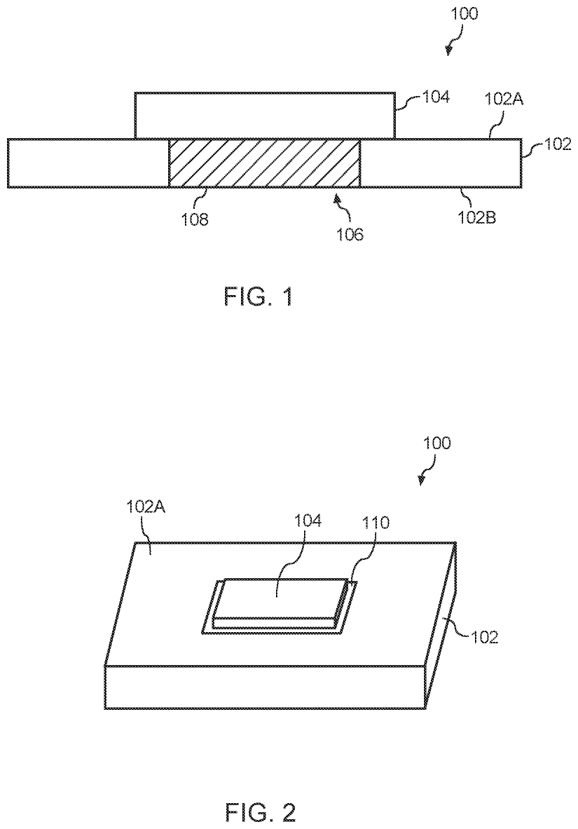

FIG. 1 depicts a cross-sectional view of a semiconductor package 100 according to example embodiments of the present disclosure. The semiconductor package 100 may include a substrate 102. The substrate 102 may be, for instance, a lead frame or other supporting structure of a wide band gap power semiconductor device, such as a silicon carbide-based semiconductor power module or discrete package. The substrate 102 may be, for instance, a copper substrate 102 or may include other suitable conducting material(s). The substrate 102 may be, for instance, a copper lead frame for the semiconductor package 100. The substrate 102 may have a first surface 102A and an opposing second surface 102B.

The semiconductor package 100 may include a semiconductor die 104. The semiconductor die 104 may include one or more devices, such as one or more of a wide variety of power devices available for different applications including, for example, power switching devices and/or power amplifiers. In some examples, the semiconductor die 104 may include one or more transistor devices, such as field effect transistors (FETs) devices, including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistor devices, etc. In some embodiments, the semiconductor die 104 may include one or more diodes (e.g., Schottky diodes, light emitting diodes, etc.).

In some embodiments, the semiconductor die 104 may be fabricated from wide band gap semiconductor materials (e.g., having a band gap greater than 1.40 eV). For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities.

Aspects of the present disclosure are discussed with reference to wide band gap semiconductors for purposes of illustration and discussion. Those of ordinary skill in the art, using the disclosures provided herein, will understand that the die-attach materials according to example embodiments of the present disclosure may be used with any semiconductor material or other material without deviating from the scope of the present disclosure.

The semiconductor die 104 may be attached to the substrate 102 using an electroless die-attach process according to example embodiments of the present disclosure. More specifically, the substrate 102 may include a through hole 106. The through hole 106 may extend through the substrate 102. For instance, the through hole 106 may extend from the first surface 102A to the second surface 102B. The semiconductor die 104 may be on the substrate 102, such as on the first surface 102A of the substrate 102. The semiconductor die 104 may be overlapping the through hole 106. In some examples, the semiconductor die 104 may completely cover the through hole 106. For instance, an area of the through hole 106 in a plane that is parallel to the semiconductor die 104 may be less than an area of the semiconductor die 104 such that the semiconductor die 104 completely covers the through hole 106. As will be discussed in more detail below, the through hole 106 may be filled with an electroless deposited portion 108 to provide a thermal, electrical, and/or mechanical connection of the semiconductor die 104 to the substrate 102.

FIG. 2 depicts a perspective view of the first surface 102A of the substrate 102. As shown, the semiconductor die 104 is on the first surface 102A of the substrate 102 at a location overlapping the through hole 106 (not shown in FIG. 2). A die-attach material 110 may be at least partially around the through hole 106 (e.g., at least partially surrounding the through hole 106). The die-attach material 110 may be, for instance, a die-attach film or paste. The die-attach material 110 may be in the form of a film, ink, or paste. The semiconductor die 104 may be on the die-attach material 110 such that the die-attach material is between a peripheral portion of the semiconductor die 104 and the substrate 102. The die-attach material 110 may be cured to temporarily secure the semiconductor die 104 in place on the first surface 102A of the substrate 102 during the electroless die-attach process according to example embodiments of the present disclosure. The die-attach material 110 may be any suitable die-attach material, such as full-sintered or semi-sintered paste with conductive particles (e.g., silver particles, copper particles, core-shell particles) or other die-attach material.

As used herein, the term “bonding” or “bonding process” refers to causing a transition of a material from a first form to a second form. A bonding process may or may not require attaching a component to the material. Sintering, reflow, annealing, curing, exposing to light, and exposing to ultraviolet light are examples of bonding processes and are encompassed by the term “bonding” or “bonding process” in the disclosure and in the claims.

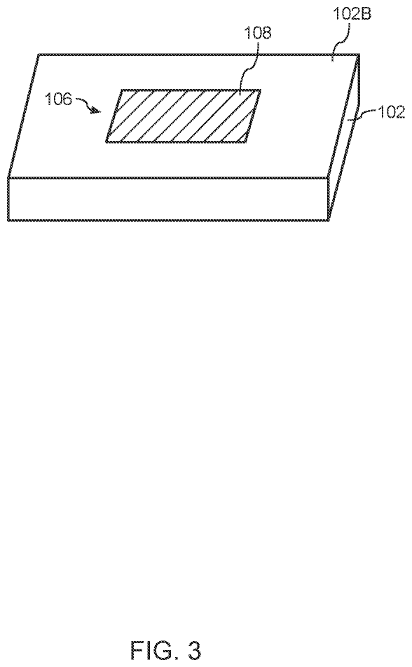

FIG. 3 depicts a perspective view of the second surface 102B of the substrate 102. As shown, the through hole 106 has been filled with an electroless deposited portion 108. The electroless deposited portion 108 may include one or more electroless deposited materials, such as electroless deposited copper and/or electroless deposited nickel. The electroless deposited portion 108 may become a part of the substrate 102. The electroless deposited portion 108 provides a thermal, mechanical, and/or electrical connection for the semiconductor die 104 to the substrate 102.

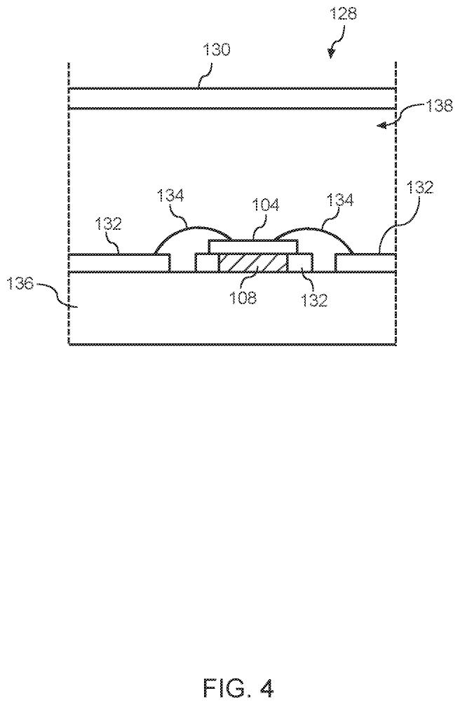

FIG. 4 depicts a portion of a power module 128 according to example embodiments of the present disclosure. FIG. 4 is intended to represent structures for identification and description and is not intended to represent the structures to physical scale. The power module 128 may include a housing 130. The power module 128 may include a conductive substrate 132 (e.g., a patterned conductive substrate) on which a semiconductor die 104 containing one or more power devices (e.g., transistors, diodes, etc.) is attached using the electroless die-attach process according to example embodiments of the present disclosure. An electroless deposited portion 108 may provide a thermal, mechanical, and/or electrical connection between the semiconductor die 104 and the conductive substrate 132. In some embodiments, the semiconductor die 104 may also be connected to the conductive substrate 132 using wire bonds 134. The conductive substrates 132 may be mounted on a base layer 136 (e.g., an insulating layer). An inert gel 138 may fill the space between the semiconductor die 104 and the housing 130.

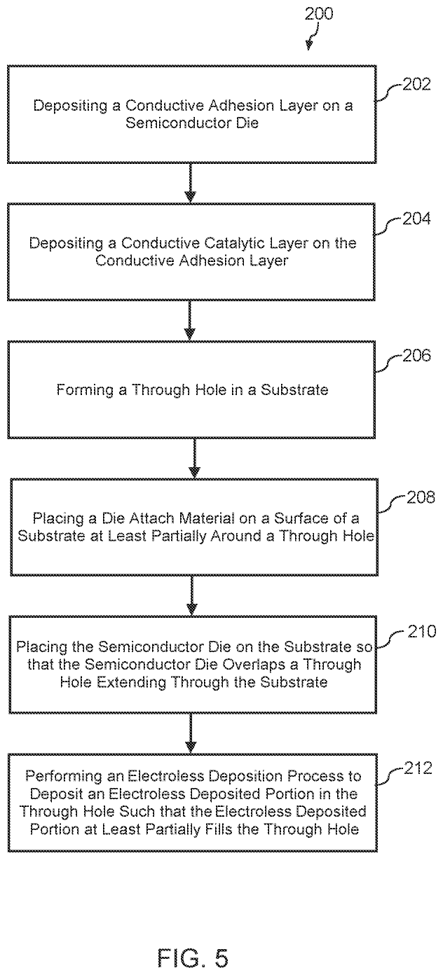

FIG. 5 depicts a flow chart of an example method 200 for conducting an electroless die-attach process according to example embodiments of the present disclosure. FIG. 5 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 202, the method 200 may include depositing a conductive adhesion layer on the semiconductor die. For instance, the conductive adhesion layer may be deposited on the surface of the semiconductor die that will be facing the substrate to which the semiconductor die will be attached. The conductive adhesion layer may include, for instance, a conductive material to facilitate adhesion of a conductive catalytic layer and/or an electroless deposited material to the semiconductor die. The conductive adhesion layer may also act as a diffusion barrier. In some examples, the conductive adhesion layer includes titanium. In some examples, the conductive adhesion layer may have a thickness, for instance, in a range of about 25 nm to about 100 nm. The conductive adhesion layer may be deposited on the semiconductor die using any suitable deposition process, such as a sputtering, evaporation, etc.

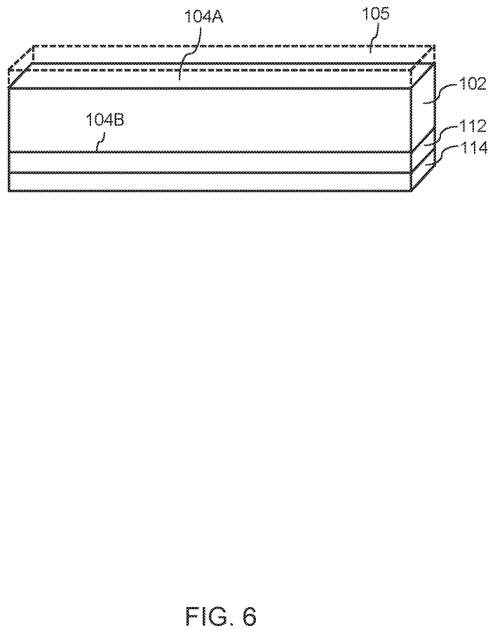

FIG. 6 depicts an example semiconductor die 104. The semiconductor die 104 includes a first surface 104A and a second surface 104B. The second surface 104B may be the surface to be attached to a substrate and may face the substrate during the electroless die-attach process according to example embodiments of the present disclosure. The conductive adhesion layer 112 is deposited on the surface 104B of the semiconductor die.

Referring to FIG. 5 at 204, the method 200 may include depositing a conductive catalytic layer on the conductive adhesion layer. The conductive catalytic layer provides an active layer to facilitate initiation of electroless deposition of an electroless deposited material. In some embodiments, the conductive catalytic layer includes gold (Au), palladium (Pd), nickel (Ni), or aluminum (Al). The conductive catalytic layer be an alloy containing gold (Au), palladium (Pd), nickel (Ni), or aluminum (Al) with other elements. For instance, the conductive catalytic layer may be a gold alloy, palladium alloy, nickel alloy, or aluminum alloy. In some examples, the conductive catalytic layer may have a thickness, for instance, in a range of about 25 nm to about 100 nm. The conductive catalytic layer may be deposited on the semiconductor die using any suitable deposition process, such as sputtering, evaporation, etc.

FIG. 6 depicts an example conductive catalytic layer 114 on the conductive adhesion layer 112 on a semiconductor die 104 according to example embodiments of the present disclosure. Other metal and/or conductive layers may be on the semiconductor die 104 between the conductive adhesion layer 112 and the conductive catalytic layer 114 without deviating from the scope of the present disclosure. In some examples, a protective coating 105 may be deposited on the semiconductor die 104. The protective coating 105 may be, for instance, photoresist or other protective material.

Referring to FIG. 5, at 206, the method 200 may include forming a through hole in a substrate, such as a conductive substrate. The through hole may be formed through any suitable process. For instance, the through hole may be formed in the conductive substrate using a punch tool or other suitable tool.

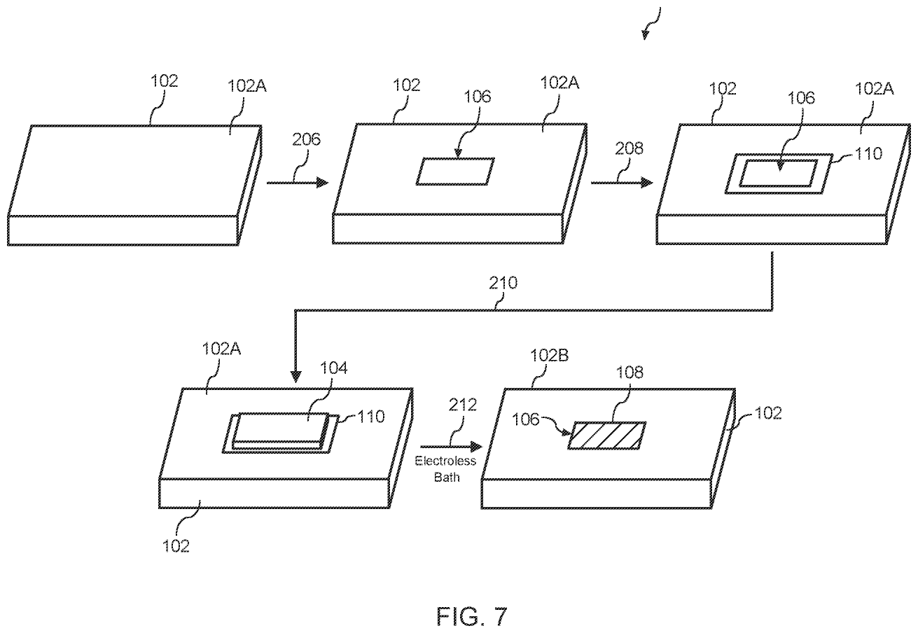

FIG. 7 depicts aspects of an electroless deposition process according to example embodiments of the present disclosure. In FIG. 7, as represented by arrow 206, a through hole 106 may be formed in a substrate 102. The through hole 106 may extend all the way through the substrate 102. For instance, the through hole 106 may extend from the first surface 102A to the second surface 102B of the substrate 102.

Referring to FIG. 5 at 208, the method 200 may include depositing a die-attach material on a surface of the substrate at least partially surrounding the through hole. The die-attach material may be deposited, for instance, using inkjet, dispense, screen printer, flexo printer, gravure printer, spin coater, blade coater, spray coater, or other deposition technique(s).

For instance, as represented by arrow 208 of FIG. 7, a die-attach material 110 may be deposited on the surface 102A of the substrate 102 at least partially surrounding (e.g., fully surrounding) the through hole 106. The die-attach material 110 may be, for instance, a die-attach film or paste. The die-attach material 110 may be in the form of a film, ink, or paste. The die-attach material 110 may be any suitable die-attach material, such as full-sintered or semi-sintered paste with conductive particles (e.g., silver particles, copper particles, core-shell particles) or other die-attach material.

Referring to FIG. 5 at 210, the method 200 may include placing the semiconductor die on the substrate so that the semiconductor die overlaps the through hole extending through the substrate. The semiconductor die may be placed on the die-attach material at least partially around (e.g., partially surrounding) the through hole.

For instance, as represented by arrow 210 of FIG. 7, the semiconductor die 104 may be placed on the substrate 102 overlapping the through hole 106 on the die-attach material 110. The die-attach material 110 may be bonded to at least temporarily attach or secure the semiconductor die 104 in place on the first surface 102A of the substrate 102 during the electroless die-attach process according to example embodiments of the present disclosure.

Referring to FIG. 5 at 212, the method 200 may include performing an electroless deposition process to deposit an electroless deposited portion in the through hole such that the electroless deposited portion at least partially fills the through hole. For instance, the substrate with semiconductor die at least temporarily bonded to the substrate may be placed in an electroless bath to deposit an electroless deposited portion in the through hole. More specifically, an electroless deposited material (e.g., copper and/or nickel) may grow in the through hole to form the electroless deposited portion while the substrate and semiconductor die are in the electroless bath. Details concerning example electroless bath chemistries are provided below.

For instance, as represented by arrow 212 of FIG. 7, the electroless deposited portion 108 may be deposited in the through hole 106 of the substrate. More particularly, FIG. 7 depicts the second surface 102B of the substrate 102 after the electroless deposition process represented by arrow 212 (e.g., placing in an electroless bath). As shown, an electroless deposited portion 108 may fill the through hole 106. The electroless deposited portion 108 may provide a thermal, mechanical, and/or electrical connection of the semiconductor die 104 to the substrate 102.

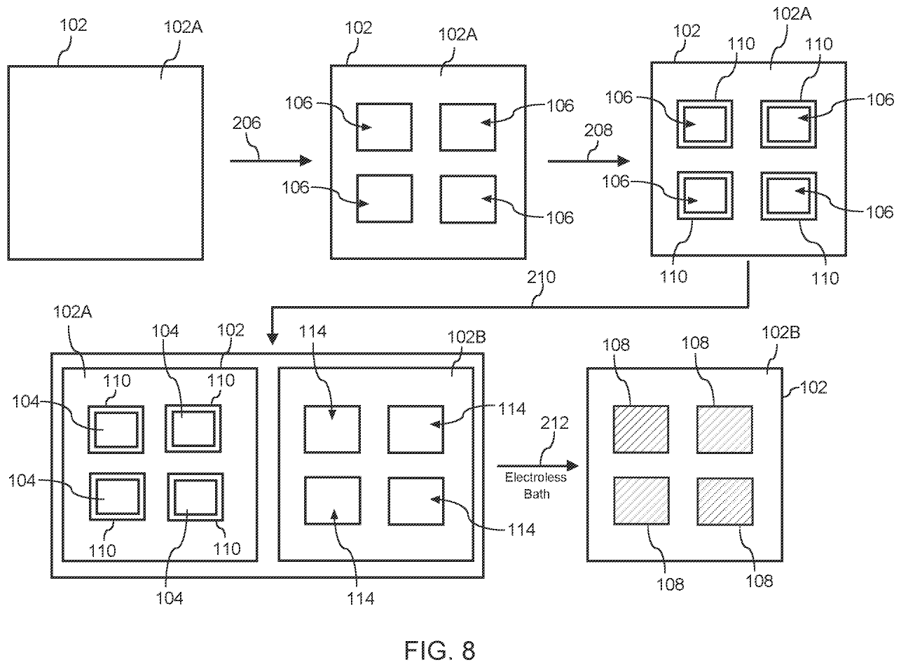

FIG. 8 depicts an electroless die-attach process according to example embodiments of the present disclosure. The electroless die-attach process in FIG. 8 is similar to the electroless die-attach process in FIG. 7, except that the electroless die-attach process is conducted in a plurality of through holes 106 formed in the substrate 102. FIG. 8 depicts an example implementation with four through holes 106 on a substrate 102 for purposes of illustration and discussion. Those of ordinary skill in the art, using the disclosures provided herein, will understand that more or fewer through holes can be used without deviating from the scope of the present disclosure.

For instance, as represented by arrow 206, a plurality of through holes 106 may be formed in the substrate 102. As represented by arrow 208, die-attach material 110 may be placed around each of the plurality of through holes 106. As represented by arrow 210, a semiconductor die 104 may be placed overlapping each of the through hole 106. FIG. 8 depicts the first surface 102A of the substrate 102 and the second surface 102B of the substrate after the semiconductor die 104 has been placed on each of the through holes 106. As shown, the conductive catalytic layer 114 deposited on the semiconductor die is visible through each of the through holes 106 from the second surface 102B of the substrate 102. As represented by arrow 212, an electroless deposition process (e.g., placing in an electroless bath) may deposit an electroless deposited portion 108 in each of the plurality of through holes 106.

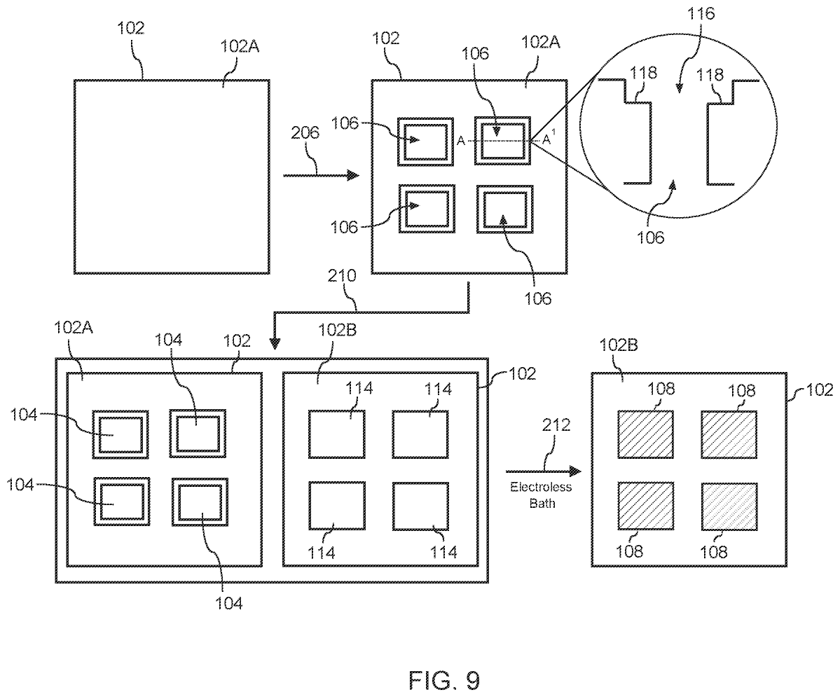

FIG. 9 depicts an electroless die-attach process according to example embodiments of the present disclosure. The electroless die-attach process in FIG. 9 is similar to that of FIGS. 7 and 8, except that the through holes have a different configuration to accommodate a semiconductor die recessed into the substrate.

For instance, as represented by arrow 206, a plurality of through holes 106 may be formed in the substrate 102. As indicated by the cross-section take along line A-A′, each through hole 106 may be formed beneath a recess 116 in the substrate 102. A stepped surface 118 may be in the recess 116. The recess 116 may be able to accommodate a semiconductor die 104, for instance, on the stepped surface 118.

More particularly, as represented by arrow 210, a semiconductor die 104 may be placed in the recess 116 overlapping the through 106. The semiconductor die 104 may be at least partially on the stepped surface 118. The semiconductor die 104 may be placed on the stepped surface 118 in the recess with or without a die-attach material.

FIG. 9 depicts the first surface 102A of the substrate 102 and the second surface 102B of the substrate after the semiconductor die 104 has been placed over each of the through holes 106. As shown, the conductive catalytic layer 114 deposited on the semiconductor die is visible through each of the through holes 106 from the second surface 102B of the substrate 102. As represented by arrow 212, an electroless deposition process (e.g., placing in an electroless bath) may deposit an electroless deposited portion 108 in each of the plurality of through holes 106.

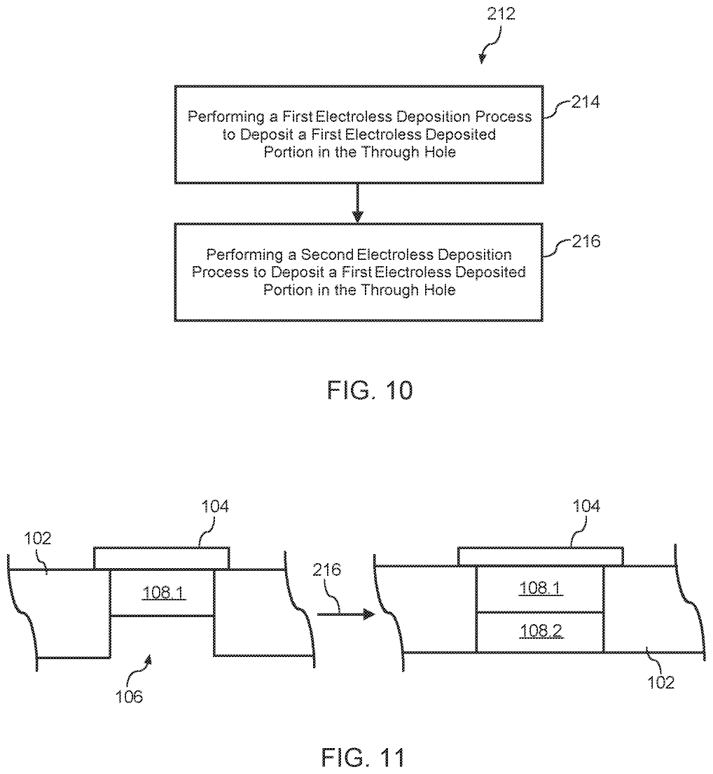

Referring to FIG. 10, in some embodiments, the electroless die-attach process may deposit different electroless material portions in the through hole. More particularly, the electroless deposition process 212 may include at 214 performing a first electroless deposition process (e.g., placing in a first electroless bath) to deposit a first electroless deposited portion in the through hole. The electroless deposition process 212 may include at 216 performing a second electroless deposition process (e.g., placing in a second electroless bath) to deposit a second electroless deposited portion in the through hole. One or more additional electroless deposition processes may be performed to deposit additional electroless deposition portions in the through hole.

For instance, FIG. 11 depicts a first electroless deposition portion 108.1 partially filling a through hole 106 in a substrate 102 after performing a first electroless deposition process. The first electroless deposition portion 108.1 may be a first material, such as copper. FIG. 11 further depicts a second electroless deposition portion 108.2 filling the remainder of the through hole after implementation of a second electroless deposition process as represented by arrow 216. The second electroless deposition portion 108.2 may be a different material relative to the first electroless deposition portion 108.1. For instance, in some examples, the first electroless deposition portion 108.1 may be copper and the second electroless deposition portion 108.2 may be nickel. In some examples, the first electroless deposition portion 108.1 may be nickel and the second electroless deposition portion 108.2 may be copper.

### Examples of Electroless Bath

An electroless bath may include a metal ion source, a reducing agent, and/or a complexing agent (e.g., chelating agent). The electroless bath may include additives as stabilizer also to tune the properties of the deposit. The pH and temperature may also be adjusted.

Examples of a metal ion source, such as a copper metal ion source are cupric salts, such as sulfate (CuSO₄), chloride (CuCl₂) or nitrate (Cu(NO₃)₂). Example reducing agents may include borohydride (e.g., NaBH₄), formaldehyde (CH₂O), hypophosphite (e.g., NaPO₂H₂), hydrazine (N₂H₄), dimethylamine borane (C₂H₇BN), and dithionite (e.g., (NaHSO₃). In some examples, formaldehyde is a preferred reducing agent due to availability and cost. Example complexing/chelating agents may include tartrate salts such as sodium tratrate (C₄H₄Na₂O₆), ethylenediamine tetraacetic acid (EDTA), alkanol amines, such as quadrol (N,N,N′,N′-tetrakis(2-hydroxypropyl)ethylenediamine), glycolic acids and other amines are examples of a complexing/chelating agents. Example additives may include 2-mercaptobenzothiazole (C₇H₅NS₂), diethyldithiocarbamate (5H₁₀NS₂), 2,2′-dipyridyl (C₁₀H₅NS₂), polyethylene glycol, vanadium pentoxide (V₂O₅), nickel chloride (NiCl₂), potassium ferrocyanide (K₄[Fe(CN)₆]). Plating rate and thickness may be tuned via different bath formulations.

### Example 1

An electroless bath is formulated using 2.8-3.5 (g/L) of CuSO₄, 35-45 (g/L) of EDTA, 1.5-1.8 g/L of formaldehyde as reducing agent, 2.5-3 (g/L) NaOH to make the bath alkaline, 1.5-2 (g/L) of 2-mercaptobenzothiazole as bath stabilizer. During the electroless deposition, the bath is heated to 65-70)(C°).

### Example 2

An electroless bath is formulated using 3-3.3 (g/L) of Cu(NO₃)₂, 10-15 (g/L) of sodium tartrate as chelating agent, 1.5-1.8 g/L of NaPO₂H₂ as reducing agent, 2.5-3 (g/L) NaOH to make the bath alkaline, 1.5-2 (g/L) 2,2′-dipyridyl as bath stabilizer and to prevent the catalytic oxidation of hypophosphite. During the electroless deposition, the bath temperature is maintained at 45-50 (C°).

Example aspects of the present disclosure are set forth below. Any of the below features or examples may be used in combination with any of the embodiments or features provided in the present disclosure.

One example embodiment of the present disclosure is directed to a semiconductor package. The semiconductor package may include a substrate comprising a through hole extending through the substrate. The semiconductor package may include a semiconductor die on the substrate. The semiconductor die may be overlapping the through hole. The through hole in the substrate may be at least partially filled with an electroless deposited portion.

In some examples, an area of the through hole in a plane that is parallel to the semiconductor die may be less than an area of the semiconductor die.

In some examples, the electroless deposited portion may be coupled to the semiconductor die.

In some examples, the electroless deposited portion comprises copper. In some examples, the electroless deposited portion comprises nickel.

In some examples, the electroless deposited portion comprises a first electroless deposited portion in the through hole and a second electroless deposited portion in the through hole. In some examples, the first electroless deposited portion comprises copper and the second electroless deposited portion comprises nickel.

In some examples, the semiconductor package comprises a conductive catalytic layer on the semiconductor die. In some examples, the conductive catalytic layer comprises one or more of gold, palladium, nickel, or aluminum. In some examples, the conductive catalytic layer comprises one or more of a gold alloy, a palladium alloy, a nickel alloy, or an aluminum alloy.

In some examples, the semiconductor package comprises a conductive adhesion layer between the conductive catalytic layer and the semiconductor die. In some examples, the conductive adhesion layer comprises titanium.

In some examples, the semiconductor package includes a die-attach material between a peripheral portion of the semiconductor die and the substrate. In some examples, the die-attach material at least partially surrounds the through hole on a surface of the substrate.

In some examples, the substrate comprises a first surface and an opposing second surface, the substrate comprising a recess in the first surface, the recess overlapping the through hole. In some examples, the semiconductor die is in the recess. In some examples, the substrate comprises a stepped surface in the recess. In some examples, a peripheral portion of the semiconductor die is on the stepped surface.

In some examples, the substrate is a conductive substrate. In some examples, the substrate comprises a lead frame. In some examples, the substrate comprises copper.

In some examples, the semiconductor die comprises a wide band gap semiconductor. In some examples, the semiconductor die comprises silicon carbide.

Another example embodiment of the present disclosure is directed to a method. The method may include placing a semiconductor die on a substrate so that the semiconductor die overlaps a through hole extending through the substrate. The method may include performing an electroless deposition process to deposit an electroless deposited portion in the through hole such that the electroless deposited portion at least partially fills the through hole.

In some examples, the electroless deposited portion comprises copper. In some examples, the electroless deposited portion comprises nickel.

In some examples, performing the electroless deposition process comprises performing a first electroless deposition process to deposit a first electroless deposited portion in the through hole and performing a second electroless deposition process to deposit a second electroless deposited portion in the through hole. In some examples, the first electroless deposited portion comprises copper and the second electroless deposited portion comprises nickel.

In some examples, the method comprises: depositing a conductive adhesion layer on the semiconductor die; and depositing a conductive catalytic layer on the conductive adhesion layer. In some examples, the conductive catalytic layer comprises one or more of gold, palladium, nickel, or aluminum. In some examples, the conductive catalytic layer comprises one or more of a gold alloy, a palladium alloy, a nickel alloy, or an aluminum alloy. In some examples, the conductive catalytic layer has a thickness in a range of about 25 nm to about 75 nm. In some examples, the conductive adhesion layer comprises titanium.

In some examples, the method includes placing a die-attach material on a surface of the substrate at least partially around the through hole. In some examples, placing a semiconductor die on a substrate comprises attaching the semiconductor die to the substrate with the die-attach material.

In some examples, placing a semiconductor die on a substrate comprises placing the semiconductor die on a stepped surface defined in a recess overlapping the through hole on the substrate.

In some examples, performing an electroless deposition process comprises placing the substrate in an electroless bath. In some examples, the electroless bath comprises a metal ion source and a reducing agent. In some examples, the electroless bath comprises a complexing agent and a stabilizer.

In some examples, the semiconductor die comprises a wide band gap semiconductor. In some examples, the semiconductor die comprises silicon carbide.

Another example embodiment of the present disclosure is directed to a power semiconductor device. The power semiconductor device may include a substrate. The power semiconductor device may include a power semiconductor die comprising a wide band gap semiconductor. The power semiconductor die may be coupled to the substrate with an electroless deposited portion.

In some examples, the electroless deposited portion comprises copper. In some examples, the electroless deposited portion comprises nickel.

In some examples, the electroless deposited portion at least partially fills a through hole in the substrate. In some examples, an area of the through hole in a plane that is parallel to the power semiconductor die is less than an area of the power semiconductor die.

In some examples, the electroless deposited portion comprises a first electroless deposited portion in the through hole and a second electroless deposited portion in the through hole. In some examples, the first electroless deposited portion comprises copper and the second electroless deposited portion comprises nickel.

In some examples, the power semiconductor device comprises a conductive catalytic layer on the power semiconductor die. In some examples, wherein the conductive catalytic layer comprises one or more of gold, palladium, nickel, or aluminum. In some examples, the conductive catalytic layer comprises one or more of a gold alloy, a palladium alloy, a nickel alloy, or an aluminum alloy.

In some examples, the power semiconductor device comprises a conductive adhesion portion between the conductive catalytic layer and the semiconductor die. In some examples, the conductive adhesion layer comprises titanium.

In some examples, the device includes a die-attach material between a peripheral portion of the power semiconductor die and the substrate. In some examples, the die-attach material at least partially surrounds a through hole in the substrate.

In some examples, the substrate comprises a first surface and an opposing second surface, the substrate comprising a recess in the first surface, the recess overlapping a through hole. In some examples, the power semiconductor die is in the recess. In some examples, the substrate comprises a stepped surface in the recess. In some examples, a peripheral portion of the power semiconductor die is on the stepped surface.

In some examples, the substrate comprises a lead frame. In some examples, the substrate comprises copper. In some examples, the power semiconductor die comprises silicon carbide.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor package, comprising:
a substrate comprising a through hole extending through the substrate; and
a semiconductor die on the substrate, the semiconductor die overlapping the through hole;
wherein the through hole in the substrate is at least partially filled with an electroless deposited portion.

2. The semiconductor package of claim 1, wherein an area of the through hole in a plane that is parallel to the semiconductor die is less than an area of the semiconductor die.

3. The semiconductor package of claim 1, wherein the electroless deposited portion is coupled to the semiconductor die.

4. The semiconductor package of claim 1, wherein the electroless deposited portion comprises copper or nickel.

5. (canceled)

6. The semiconductor package of claim 1, wherein the electroless deposited portion comprises a first electroless deposited portion in the through hole and a second electroless deposited portion in the through hole.

7. The semiconductor package of claim 6, wherein the first electroless deposited portion comprises copper and the second electroless deposited portion comprises nickel.

8. The semiconductor package of claim 1, wherein the semiconductor package comprises a conductive catalytic layer on the semiconductor die.

9. The semiconductor package of claim 8, wherein the conductive catalytic layer comprises one or more of gold, palladium, nickel, or aluminum.

10. The semiconductor package of claim 9, wherein the conductive catalytic layer comprises one or more of a gold alloy, a palladium alloy, a nickel alloy, or an aluminum alloy.

11. The semiconductor package of claim 8, wherein the semiconductor package comprises a conductive adhesion layer between the conductive catalytic layer and the semiconductor die.

12. The semiconductor package of claim 11, wherein the conductive adhesion layer comprises titanium.

13. The semiconductor package of claim 1, further comprising a die-attach material between a peripheral portion of the semiconductor die and the substrate, wherein the die-attach material at least partially surrounds the through hole on a surface of the substrate.

14. (canceled)

15. The semiconductor package of claim 1, wherein the substrate comprises a first surface and an opposing second surface, the substrate comprising a recess in the first surface, the recess overlapping the through hole.

16. The semiconductor package of claim 15, wherein the semiconductor die is in the recess.

17. The semiconductor package of claim 16, wherein the substrate comprises a stepped surface in the recess, wherein a peripheral portion of the semiconductor die is on the stepped surface.

18. (canceled)

19. The semiconductor package of claim 1, wherein the substrate is a conductive substrate.

20.-22. (canceled)

22. The semiconductor package of claim 1, wherein the semiconductor die comprises a wide band gap semiconductor.

23. The semiconductor package of claim 1, wherein the semiconductor die comprises silicon carbide.

24. A method, comprising:
placing a semiconductor die on a substrate so that the semiconductor die overlaps a through hole extending through the substrate; and
performing an electroless deposition process to deposit an electroless deposited portion in the through hole such that the electroless deposited portion at least partially fills the through hole.

25.-41. (canceled)

42. A power semiconductor device, comprising:
a substrate; and
a power semiconductor die comprising a wide band gap semiconductor, the power semiconductor die coupled to the substrate with an electroless deposited portion.

43.-62. (canceled)
